(19) United States
(12) Patent Application Publication
(10) Pub. No.: US 2026/0255823 A1
(43) Pub. Date: Aug. 27, 2026

(54) ELECTRONIC DEVICE, METHOD OF MANUFACTURING DISPLAY DEVICE, AND METHOD OF INSPECTING THE DISPLAY DEVICE

(71) Applicant: Samsung Display Co., LTD., Yongin-si (KR)

(72) Inventors: SUNG-JIN YANG, Yongin-si (KR); Daewoon KIM, Yongin-si (KR); HYUNSIK PARK, Yongin-si (KR)

(21) Appl. No.: 19/390,890

(22) Filed: Nov. 17, 2025

(30) Foreign Application Priority Data
Feb. 27, 2025 (KR) 10-2025-0026183
Apr. 21, 2025 (KR) 10-2025-0051698

(51) Int. Cl. H10K 59/131; H10K 59/12; H10K 59/88; H10K 71/70

(52) U.S. Cl. CPC H10K 59/131; H10K 59/1201; H10K 59/88; H10K 71/70

(57) ABSTRACT

An electronic device includes a display panel. The display panel includes a pixel, a power voltage line which supplies a voltage to the pixel, a power pad electrically connected to the power voltage line, where the power pad includes a connection part and a protrusion part protruding from the connection part in a first direction, a first inspection line group electrically connected to the power pad and aligned with the connection part in a second direction intersecting the first direction, and a second inspection line group electrically connected to the power pad and aligned with the protrusion part in the second direction.

This application claims priority to Korean Patent Application No. 10-2025-0026183, filed on February 27, 2025, and Korean Patent Application No. 10-2025-0051698 filed on April 21, 2025, and all the benefits accruing therefrom under 35 U.S.C. §119, the contents of which in their entireties are herein incorporated by reference.

### BACKGROUND

### (1) Field

Embodiments of the present disclosure described herein relate to an electronic device, a method of manufacturing a display device, and a method of inspecting a display device. More particularly, embodiments of the present disclosure described herein relate an electronic device including an inspection line connected to a power pad, a method of manufacturing a display device, and a method of inspecting reliability of a display device.

### (2) Description of the Related Art

Various display devices used in multimedia devices such as televisions, mobile phones, tablet computers, navigation devices, and game consoles have been developed.

An inspection pad for testing whether a display device operates normally may be disposed outside a display area of a display panel. Recently, as a border or bezel area of the display device is reduced, a method of completing inspection of the display device and then separating the inspection pad from the display device has been introduced.

### SUMMARY

During the inspection of the display device, inspection lines of the inspection pad may be lost as some of the inspection lines are burned due to a high current. As the inspection pad and the inspection lines are completely inspected and are then separated from each other, the inspection pad and the inspection lines should be determined as good products, but an inspection result may be determined to be defective.

Embodiments of the present disclosure provide an electronic device having improved inspection reliability.

Embodiments of the present disclosure also provide a method of manufacturing a display device having improved inspection reliability and a method of inspecting the display device.

According to an embodiment of the present disclosure, an electronic device includes a display panel. In such an embodiment, the display panel includes a pixel, a power voltage line which supplies a voltage to the pixel, a power pad electrically connected to the power voltage line, where the power pad includes a connection part and a protrusion part protruding from the connection part in a first direction, a first inspection line group electrically connected to the power pad and aligned with the connection part in a second direction intersecting the first direction, and a second inspection line group electrically connected to the power pad and aligned with the protrusion part in the second direction.

In an embodiment, the first inspection line group may include a plurality of first inspection lines, and the plurality of first inspection lines may be spaced apart from each other in the first direction. In such an embodiment, the second inspection line group may include a plurality of second inspection lines, and the plurality of second inspection lines may be spaced apart from each other in the first direction.

In an embodiment, the display panel may further include an insulating layer in contact with the first inspection line group and the second inspection line group. In such an embodiment, the insulating layer may include a cutting surface defining a side surface of the display panel, and each of the first inspection line group and the second inspection line group may include a cutting surface. In such an embodiment, the cutting surface of the insulating layer may be aligned with the cutting surface of each of the first inspection line group and the second inspection line group.

In an embodiment, the display panel may further include a dummy pad spaced apart from the connection part in the first direction and spaced apart from the protrusion part in the second direction. In such an embodiment, a length of the dummy pad in the second direction may be smaller than a length of the connection part in the second direction.

In an embodiment, The first inspection line group may include a first first inspection line group and a second first inspection line group spaced apart from the first first inspection line group in the first direction.

In an embodiment, the display panel may further include a base substrate, a first insulating layer disposed on the base substrate, and a second insulating layer disposed on the first insulating layer. In such an embodiment, the first inspection line group and the second inspection line group may be disposed between the first insulating layer and the second insulating layer, and the power pad may be electrically connected to the first inspection line group and the second inspection line group through a first contact hole defined through the second insulating layer.

In an embodiment, the first contact hole may be provided as a plurality of first contact holes, and, in a plan view, at least one of the plurality of first contact holes may be located inside the connection part, and at least another one of the plurality of first contact hole may be located inside the protrusion part.

In an embodiment, the second inspection line group may extend from the protrusion part in the second direction, and the second inspection line group and the protrusion part may be integrally formed as a single unitary indivisible part.

In an embodiment, the first inspection line group and the second inspection line group may be disposed in different layers, respectively.

In an embodiment, the electronic device may further include a power module which supplies power to the display panel, a processor which controls an operation of the display panel, and a circuit board connected to the connection part.

According to an embodiment of the present disclosure, a method of manufacturing a display device includes forming a preliminary display panel in which a display area, a non-display area disposed around the display area, and an inspection area extending from one end of the non-display area are defined, performing reliability inspection on inspection pads disposed inside the inspection area, and separating the inspection area from the non-display area. In such an embodiment, the preliminary display panel may include a pixel disposed inside the display area, a power voltage line which is disposed inside the non-display area and supplies a voltage to the pixel, a power pad disposed inside the non-display area and electrically connected to the power voltage line, where the power pad includes a connection part and a protrusion part protruding from the connection part in a first direction, a first inspection line group electrically connected to the power pad and aligned with the connection part in the first direction, and a second inspection line group electrically connected to the power pad and aligned with the protrusion part in the first direction. In such an embodiment, the preliminary display panel further includes a first inspection pad disposed inside the inspection area and electrically connected to the connection part through the first inspection line group and a second inspection pad electrically connected to the protrusion part through the second inspection line group.

In an embodiment, the separating the inspection area from the non-display area may be performed by laser trimming.

In an embodiment, the separating the inspection area from the non-display area may further include polishing a cutting surface of the non-display area formed by the laser trimming.

In an embodiment, the first inspection pad and the second inspection pad may extend in a second direction intersecting the first direction, and a length of the second inspection pad in the second direction may be smaller than a length of the first inspection pad in the second direction.

In an embodiment, each of the first inspection pad and the second inspection pad may have the same stacked structure as the power pad.

In an embodiment, the first inspection pad may be electrically connected to the first inspection line group through a first second contact hole, and the second inspection pad may be electrically connected to the second inspection line group through a second second contact hole spaced apart from the first second contact hole in the first direction.

According to an embodiment of the present disclosure, a method of inspecting reliability of a display device including a display panel is provided, where the display panel includes a pixel, a power voltage line electrically connected to the pixel, a power pad electrically connected to the power voltage line, where the power pad includes a connection part and a protrusion part protruding from the connection part in a first direction, a first inspection line group electrically connected to the power pad and aligned with the connection part in a second direction intersecting the first direction, a second inspection line group electrically connected to the power pad and aligned with the protrusion part in the second direction, a first inspection pad electrically connected to the first inspection line group, and a second inspection pad electrically connected to the second inspection line group, the first inspection pad and the second inspection pad being disposed inside an inspection area. In such an embodiment, the method of inspecting reliability of the display device includes performing a first inspection operation by applying a first inspection signal to the first inspection pad in a way that a reverse current flows through a light emitting element of the pixel and performing a second inspection operation by applying a second inspection signal to the second inspection pad in a way that a normal current flows through the light emitting element of the pixel.

In an embodiment, in the performing the first inspection operation, the first inspection signal may have a power voltage higher than a voltage applied to an anode of the light emitting element.

In an embodiment, in the performing the first inspection operation, a portion of the first inspection line group may be disconnected.

In an embodiment, in the performing the second inspection operation, the second inspection signal may have a power voltage lower than a voltage applied to an anode of the light emitting element.

### BRIEF DESCRIPTION OF THE DRAWINGS

The above and other features of embodiments of the present disclosure will become apparent by describing in detail embodiments thereof with reference to the accompanying drawings, in which:

FIG. 1 is a block diagram of an electronic device according to an embodiment;

FIG. 2 is a schematic view of the electronic device according to an embodiment;

FIG. 3 is a perspective view of an electronic device according to an embodiment of the present disclosure;

FIG. 4 is an exploded perspective view of the electronic device illustrated in FIG. 3;

FIG. 5 is a cross-sectional view of the display device taken along line I-I’ in FIG. 4;

FIG. 6 is a cross-sectional view of a display substrate taken along line

II-II′ in FIG. 4;

FIG. 7 is a plan view of the display substrate according to an embodiment of the present disclosure;

FIG. 8 is a plan view illustrating a preliminary display device according to an embodiment of the present disclosure;

FIG. 9A is a plan view of area AA’ in FIG. 8;

FIG. 9B is an enlarged plan view of a portion of a power pad of FIG. 9A;

FIG. 9C is a cross-sectional view taken along line II-II’ in FIG. 9B;

FIG. 10A is an enlarged plan view of a portion of the power pad cut by a cutting line;

FIG. 10B is a cross-sectional view taken along line III-III′ of FIG. 10A;

FIG. 11A is an enlarged plan view of a portion of the power pad according to an embodiment of the present disclosure;

FIG. 11B is a cross-sectional view taken along line IV-IV′ in FIG. 11A;

FIG. 12 is an enlarged plan view of a portion of the power pad according to an embodiment of the present disclosure;

FIG. 13A is a flowchart of a portion of a method of manufacturing a display device according to an embodiment of the present disclosure;

FIG. 13B is a flowchart of a method of inspecting reliability of a display device according to an embodiment of the present disclosure;

FIG. 14A is a cross-sectional view illustrating a first inspection of the display device according to an embodiment of the present disclosure; and

FIG. 14B is a cross-sectional view illustrating a second inspection of the display device according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In the specification, the expression that a first component (or an area, a layer, a part, a portion, etc.) is “connected with” or “coupled to” a second component means that the first component is directly connected with or coupled to the second component or means that a third component is interposed therebetween.

The same reference numerals refer to the same components. Further, in the drawings, the thickness, the ratio, and the dimension of components are exaggerated for effective description of technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical terms and scientific terms) used in the specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

A display device according to an embodiment may be applied to various electronic devices. An electronic device ED according to an embodiment may include the above-described display device and may further include a module or device having other additional functions in addition to the display device.

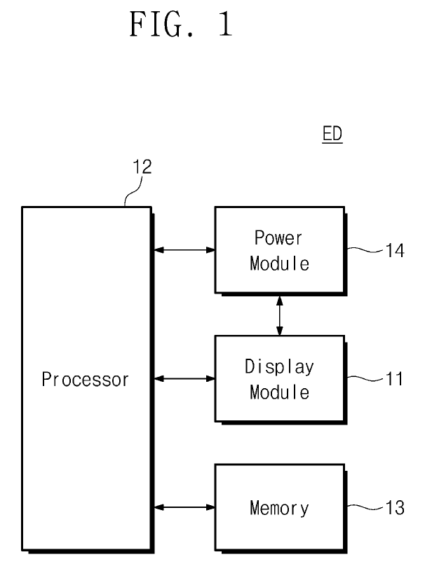

FIG. 1 is a block diagram of the electronic device ED according to an embodiment. Referring to FIG. 1, the electronic device ED according to an embodiment may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

Data information used for operations of the processor 12 or the display module 11 may be stored in the memory 13. When the processor 12 executes an application stored in the memory 13, an image data signal and/or an input control signal may be transmitted to the display module 11, and the display module 11 may process the received signal and output image information through the display screen.

The power module 14 may include a power supply module such as a power adapter or a battery device and a power conversion module that converts power supplied by a power supply module to generate power used for the operation of the electronic device ED.

At least one of the components of the electronic device ED may be included in the display device according to an embodiment. Further, some of individual modules functionally included inside one module may be included inside the display device, and the others thereof may be provided separately from the display device. In an embodiment, for example, the display device may include the display module 11, and the processor 12, the memory 13, and the power module 14 may be provided in the form of other devices in the electronic device ED rather than the display device.

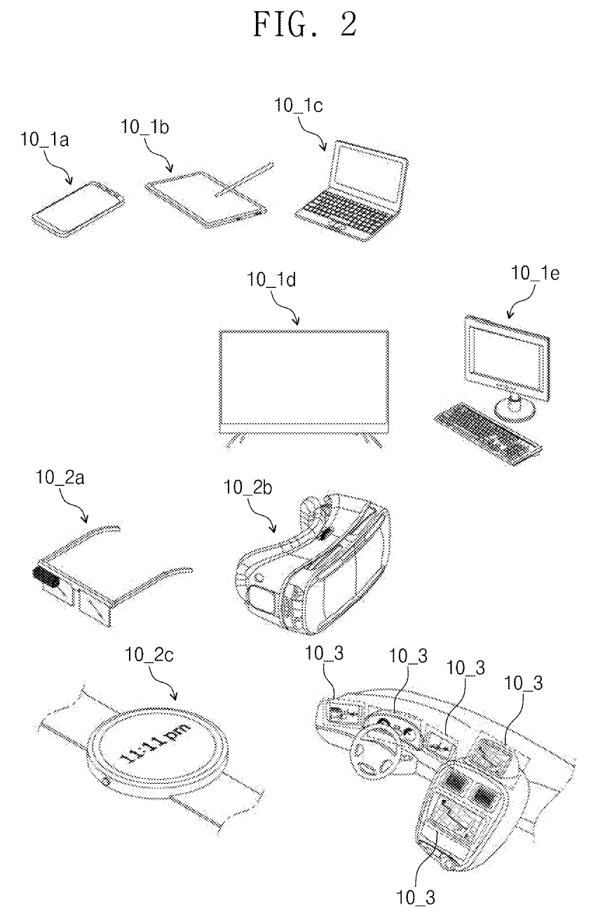

FIG. 2 is a schematic view of the electronic device according to an embodiment.

Referring to FIG. 2, various electronic devices to which the display device according to an embodiment is applied may include an image display electronic device such as a smartphone 10_1a, a tablet personal computer (PC) 10_1b, a laptop computer 10_1c, a television (TV) 10_1d, and a desk monitor 10_1e, a wearable electronic device including a display module such as a smart glasses 10_2a, a head mounted display 10_2b, and a smart watch 10_2c, and a vehicle electronic device 10_3 including a display module such as an instrument panel, a center fascia, a center information display (CID) disposed on a dashboard, and a room mirror display of a vehicle.

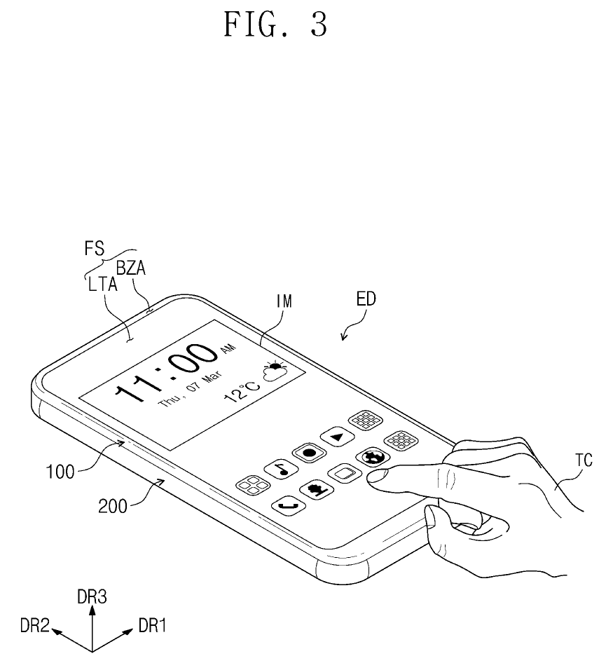

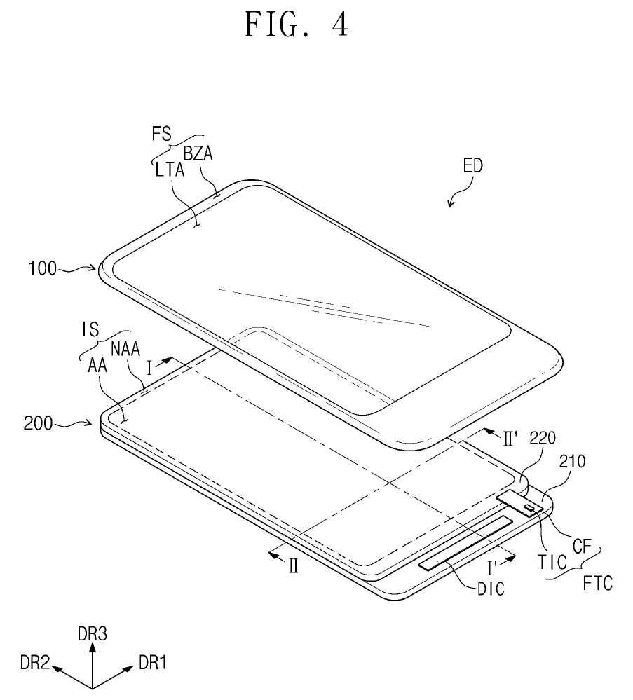

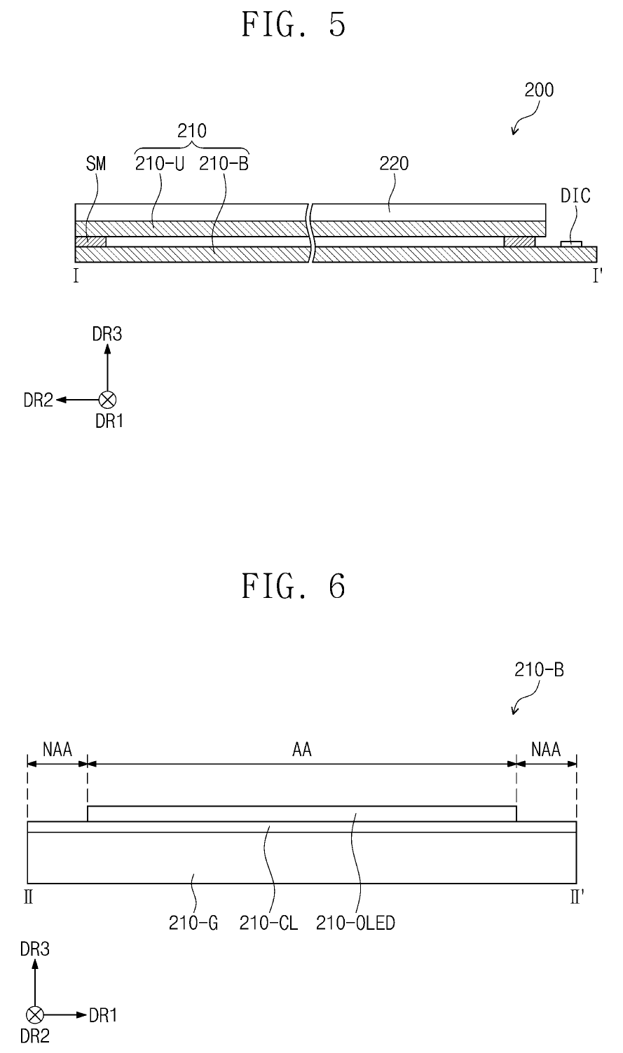

FIG. 3 is a perspective view of the electronic device ED according to an embodiment of the present disclosure. FIG. 4 is an exploded perspective view of the electronic device ED illustrated in FIG. 3. FIG. 5 is a cross-sectional view of a display device 200 taken along line I-I’ in FIG. 4.

An embodiment, the electronic device ED may be a device that is activated based on an electrical signal. The electronic device ED may include an embodiment. In an embodiment, for example, the electronic device ED may include a tablet computer, a laptop, a computer, a smart television, and the like. In an embodiment, as shown in FIG. 3, the electronic device ED may be a smartphone.

In an embodiment, the electronic device ED may display an image IM through a display surface FS. The display surface FS is parallel to a surface defined by a first direction DR1 and a second direction DR2. A normal direction of the display surface FS, i.e., a thickness direction of the electronic device ED, is indicated by a third direction DR3. Front surfaces (or upper surfaces) and rear surfaces (or lower surfaces) of members or units, which will be described below, are distinguished by the third direction DR3. Hereinafter, the first direction DR1, the second direction DR2, and the third direction DR3 are defined as directions indicated by a first direction axis, a second direction axis, and a third direction axis and refer to the same reference numerals.

The display surface FS, on which the image IM is displayed, may correspond to a front surface of the electronic device ED and may correspond to a front surface FS of a window member 100. Hereinafter, the display surface and the front surface of the electronic device ED and the front surface of the window member 100 will be designated by the same reference numerals. FIG. 3 illustrates a clock and a plurality of icons as an example of the image IM.

The electronic device ED includes the window member 100 and the display device 200. Although not separately illustrated, the electronic device ED may further include an optical member disposed between the window member 100 and the display device 200. In an embodiment, the optical member may include a polarizer. In an embodiment, the optical member may include a color filter member that decreases reflectance of an external light.

The window member 100 includes a base panel. In an embodiment, for example, the base panel may include glass, plastic, or a combination thereof. The front surface FS of the window member 100 includes a transmissive area LTA and a bezel area BZA. The transmissive area LTA may be an optically transparent area. In an embodiment, for example, the transmissive area LTA may be an area having a visible light transmittance of about 90% or greater.

The bezel area BZA may be an area having a relatively low light transmittance as compared to the transmissive area LTA. The bezel area BZA defines a shape of the transmissive area LTA. The bezel area BZA may be adjacent to the transmissive area LTA and surround the transmissive area LTA. The window member 100 may further include a light shielding pattern disposed on the base panel and defining the bezel area BZA.

The bezel area BZA may have a predetermined color. The bezel area BZA may cover a non-display area NAA of the display device 200 and prevent the non-display area NAA from being visually recognized from the outside. In the window member 100 according to another embodiment of the present disclosure, a part or the entirety of the bezel area BZA may be omitted.

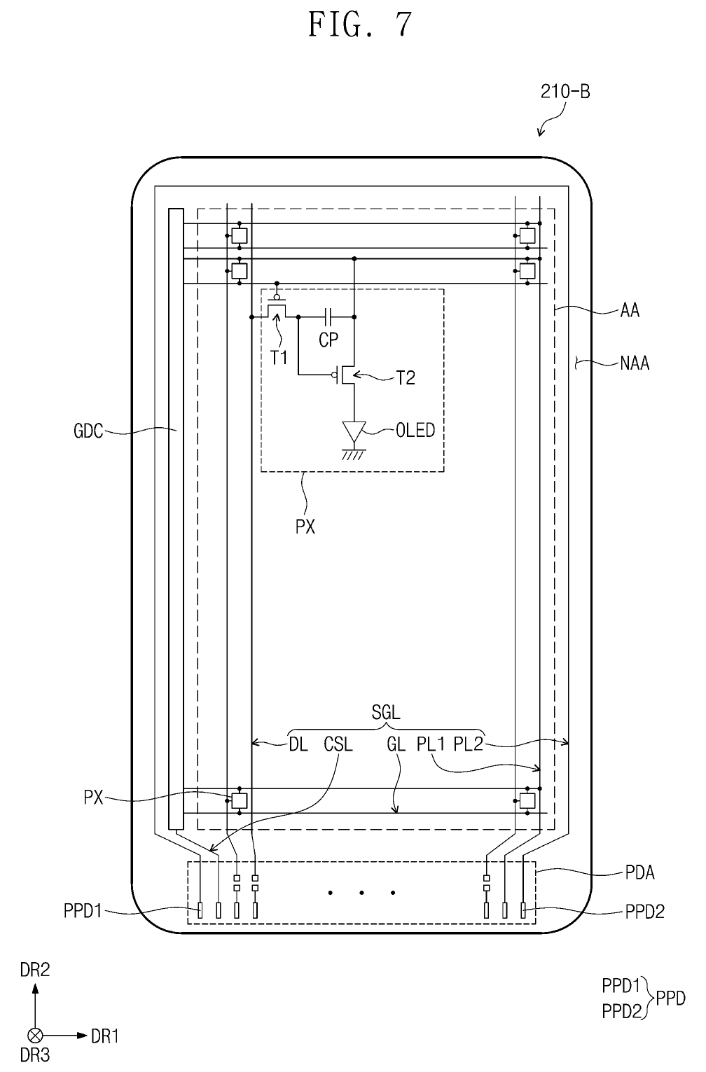

The display device 200 may display the image IM and sense an external input TC. The image IM may be disposed on the front surface FS of the display device 200. The front surface FS of the display device 200 includes a display area AA and the non-display area NAA. The display area AA may be an area that is activated response to an electrical signal. The display area AA may be an area in which pixels PX (see FIG. 7), which will be described below, overlap the same.

In an embodiment, the display area AA may be an area on which the image IM is displayed, and at the same time, an area in which the external input TC is sensed. The display area AA corresponds to the transmissive area LTA, and the non-display area NAA corresponds to the bezel area BZA. In the specification, the wording “an area/part corresponds to an area/part” means that “an area/part and an area/part overlap each other” and is not limited to a state in which the area/part and the area/part have the same area and/or the same shape.

In an embodiment, as shown in FIG. 4, the display device 200 includes a display panel 210, an input sensor 220, a driving circuit DIC, and a circuit module FTC.

The display panel 210 substantially generates the image IM. The display panel 210 may be a light emitting display panel. In an embodiment, for example, the light emitting display panel may be an organic light emitting display panel, a quantum dot light emitting display panel, or a micro light emitting diode (LED) light emitting display panel. The panels are distinguished according to a composition of a light emitting element. A light emitting layer of the organic light emitting display panel may include an organic light emitting material. A light emitting layer of the quantum dot light emitting display panel may include a quantum dot and/or a quantum rod. A light emitting layer of the micro LED light emitting display panel may include a plurality of micro LEDs. Hereinafter, for convenience of description, embodiments where the display panel 210 is an organic light emitting display panel will be mainly described, but not being limited thereto.

The input sensor 220 senses an external input (e.g., a touch event) applied from an external unit. In an embodiment, the input sensor 220 may be a capacitive touch sensor, and the present disclosure is not particularly limited thereto.

The driving circuit DIC is disposed on the display panel 210. The driving circuit DIC may be mounted on the display panel 210. The driving circuit DIC is electrically connected to the display panel 210 and provides an electrical signal for driving the display panel 210 to the display panel 210.

The circuit module FTC is electrically connected to the input sensor 220. In an embodiment, the circuit module FTC may include a flexible circuit board CF and a sensor driving circuit TIC. The flexible circuit board CF includes an insulating layer and a plurality of wiring lines. The wiring lines electrically connect the input sensor 220 and the sensor driving circuit TIC. The sensor driving circuit TIC may be mounted on the flexible circuit board CF in the form of a chip-on film.

The circuit module FTC may connect the input sensor 220 and the display panel 210. In another embodiment, the sensor driving circuit TIC may be omitted. The sensor driving circuit TIC and the driving circuit DIC may be formed integrally with each other.

Referring to FIG. 5, an embodiment of the display panel 210 includes a display substrate 210-B, an encapsulation substrate 210-U, and a sealing member SM for bonding the display substrate 210-B and the encapsulation substrate 210-U.

The display substrate 210-B includes the pixels PX (see FIG. 7) that substantially generate images. The encapsulation substrate 210-U seals the pixels PX and prevents the pixels PX from being damaged by external moisture.

The driving circuit DIC may be coupled to the display substrate 210-B. The driving circuit DIC may be provided in the form of an integrated chip. However, the present disclosure is not limited thereto, and in another embodiment, the driving circuit DIC may not be mounted on the display substrate 210-B or may be mounted on a circuit board connected to the display substrate 210-B.

The display substrate 210-B and the encapsulation substrate 210-U may serve as a base substrate and include a glass substrate. The display substrate 210-B may have a larger area than the encapsulation substrate 210-U. The driving circuit DIC may be disposed in a partial area of the display substrate 210-B, which is exposed from the encapsulation substrate 210-U. However, the present disclosure is not limited thereto, and in another embodiment, the display substrate 210-B and the encapsulation substrate 210-U may have substantially a same shape (e.g., a same planar shape) as each other. An outer surface (or an upper surface) of the encapsulation substrate 210-U may provide a base surface on which the input sensor 220 is disposed.

The sealing member SM may include, for example, a frit. The frit is a ceramic adhesive material that has a property of curing after laser exposure. The frit may contain, as main ingredients, 15 wt% to 40 wt% of V₂O₅, 10 wt% to 30 wt% of TeO₂, 1 wt% to 15 wt% of P₂O₅, 1 wt% to 15 wt% of BaO, 1 wt% to 20 wt% of ZnO, 5 wt% to 30 wt% of ZrO₂, 5 wt% to 20 wt% of WO₃, and 1 wt% to 15 wt% of BaO and may contain, as additives, at least one selected from Fe₂O₃, CuO, MnO, Al₂O₃, Na₂O, and Nb₂O₅. The frit having this composition may have a thermal expansion

coefficient of 40 to 100×10⁻⁷/E and a glass transition temperature of 250 °C. The sealing member SM overlaps the non-display area NAA.

FIG. 6 is a cross-sectional view of the display substrate 210-B taken along line II-II′ in FIG. 4. FIG. 7 is a plan view of the display substrate 210-B according to an embodiment of the present disclosure. In an embodiment, as illustrated in FIG. 6, the display substrate 210-B includes a base substrate 210-G (hereinafter, referred to as a first base substrate), a circuit element layer 210-CL disposed on an upper surface (or an inner surface) of the first base substrate 210-G, and a display element layer 210-OLED. The display substrate 210-B may further include an insulating layer that covers the display element layer 210-OLED.

The first base substrate 210-G may include a glass substrate, a metal substrate, or an organic/inorganic composite material substrate. The circuit element layer 210-CL includes at least one insulating layer and a circuit element. The insulating layer includes at least one inorganic layer and at least one organic layer. The circuit element includes signal lines, a pixel driving circuit, and the like. The display element layer 210-OLED includes at least organic light emitting diodes (OLEDs) as light emitting elements. The display element layer 210-OLED may further include an organic layer such as a pixel defining film.

In an embodiment, as illustrated in FIG. 7, the display substrate 210-B may include a driving circuit GDC, a plurality of signal lines SGL (hereinafter, referred to as signal lines), and the plurality of pixels PX (hereinafter, referred to as pixels).

The driving circuit GDC may include a scan driving circuit. The scan driving circuit generates a plurality of scan signals (hereinafter, referred to as scan signals) and sequentially outputs the scan signals to a plurality of scan lines GL (hereinafter, referred to as scan lines), which will be described below. The scan driving circuit may further output another control signal to driving circuits of the pixels PX.

The scan driving circuit may include a plurality of transistors formed through a same process as the driving circuits of the pixels PX, for example, through a low temperature polycrystalline silicon (LTPS) process and/or a low temperature polycrystalline oxide (LTPO) process.

The signal lines SGL include the scan lines GL, data lines DL, power lines PL1 and PL2, and a control signal line CSL. Each of the scan lines GL is connected to a corresponding pixel PX among the pixels PX, and each of the data lines DL is connected to a corresponding pixel PX among the pixels PX. The power lines PL1 and PL2 are connected to the pixels PX. The control signal line CSL may provide control signals to the scan driving circuit.

The power lines PL1 and PL2 include the first power line PL1 and the second power line PL2. The first power line PL1 may extend in the second direction DR2. The second power line PL2 may have a loop shape having one open side and partially surround the display area AA. Each of the pixels PX may receive a first power voltage through the first power line PL1 from a first power voltage line and may receive a second power voltage through the second power line PL2 from a second power voltage line. The first power voltage may have a higher level than that of the second power voltage.

The display area AA may be defined as an area in which the pixels PX are arranged. A plurality of electronic elements are arranged in the display area AA. The electronic elements include an organic light emitting diode provided in each of the pixels PX and a pixel driving circuit connected thereto. The driving circuit GDC, the signal lines SGL, and the pixel driving circuit may be included in the circuit element layer 210-CL illustrated in FIG. 6.

The pixel PX may include, for example, a first transistor T1, a second transistor T2, a capacitor CP, and an organic light emitting diode OLED. The pixel driving circuit includes a switching transistor and a driving transistor and is not limited to an embodiment of a connection relationship between transistors and a capacitor illustrated in FIG. 7. The first transistor T1 is connected to the scan line GL and the data line DL. An anode of the organic light emitting diode OLED may receive the first power voltage provided by the first power line PL1, and a cathode thereof may receive the second power voltage provided by the second power line PL2.

In an embodiment, as illustrated in FIG. 7, a pad area PDA in which a plurality of pads are arranged, is defined in the non-display area NAA. The driving circuit DIC (see FIG. 4) may be mounted to partially overlap the pad area PDA. The driving circuit DIC may be connected to the data lines DL. The pads connected to the power lines PL1 and PL2 in the pad area PDA may be referred to as power pads. In an embodiment, for example, among the pads electrically connected to the second power line PL2, a pad disposed on a left side in the first direction DR1 may be a first power pad PPD1, and a pad disposed on a right side may be a second power pad PPD2. Power pads PPD may include the first power pad PPD1 and the second power pad PPD2 and may also include pads electrically connected to the first power line PL1.

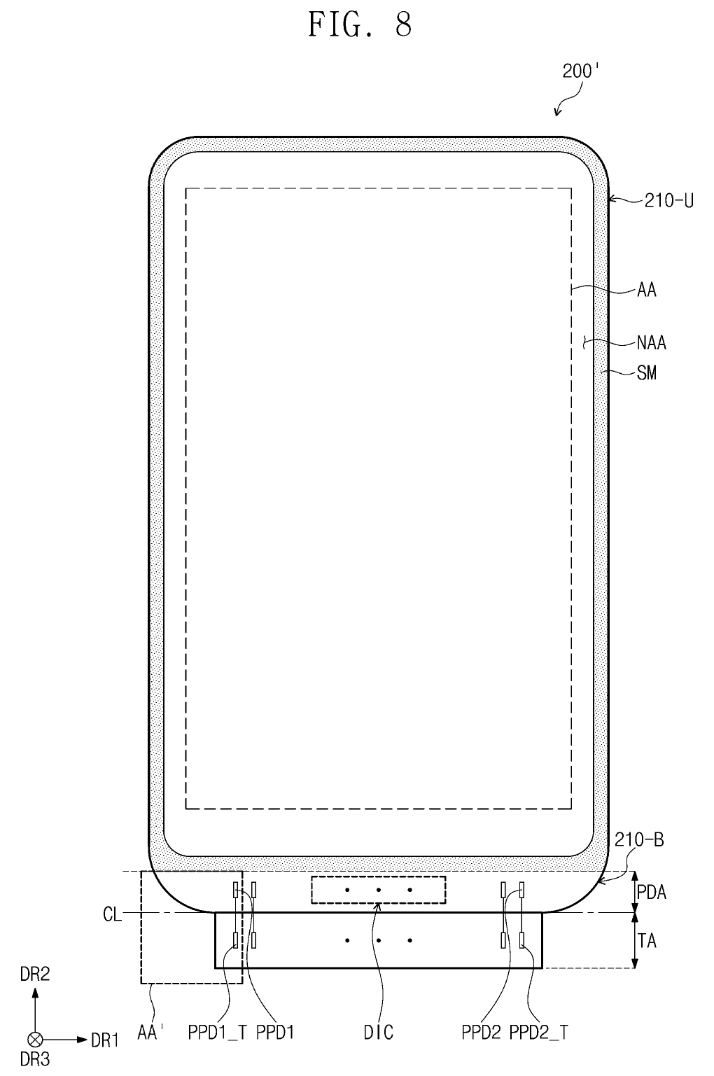

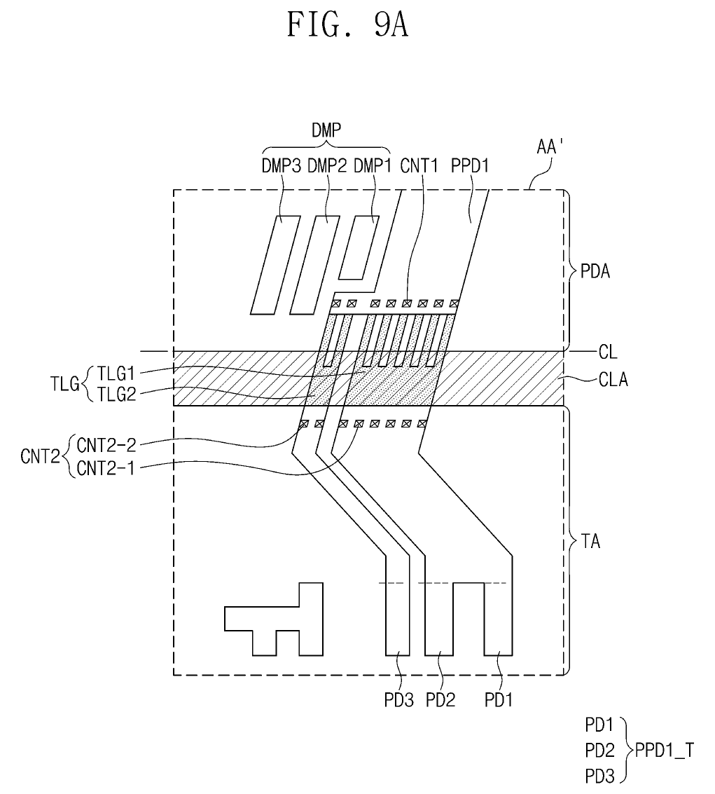

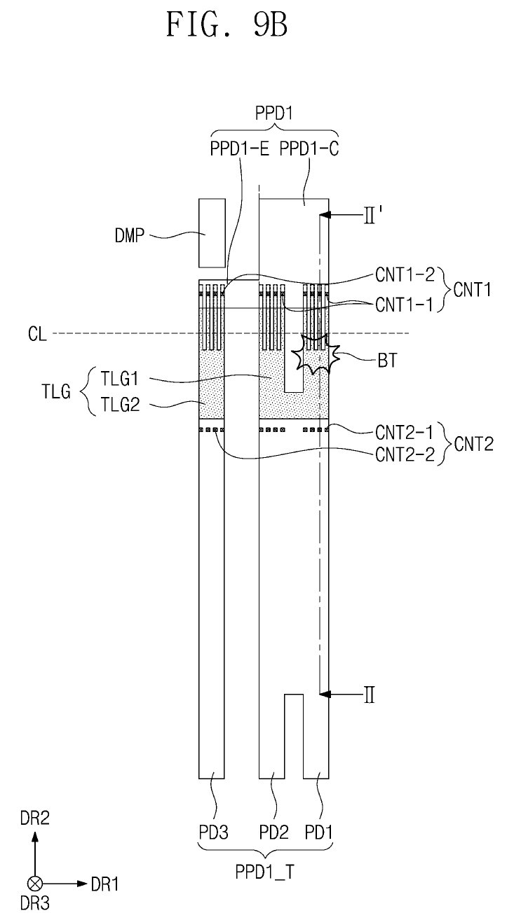

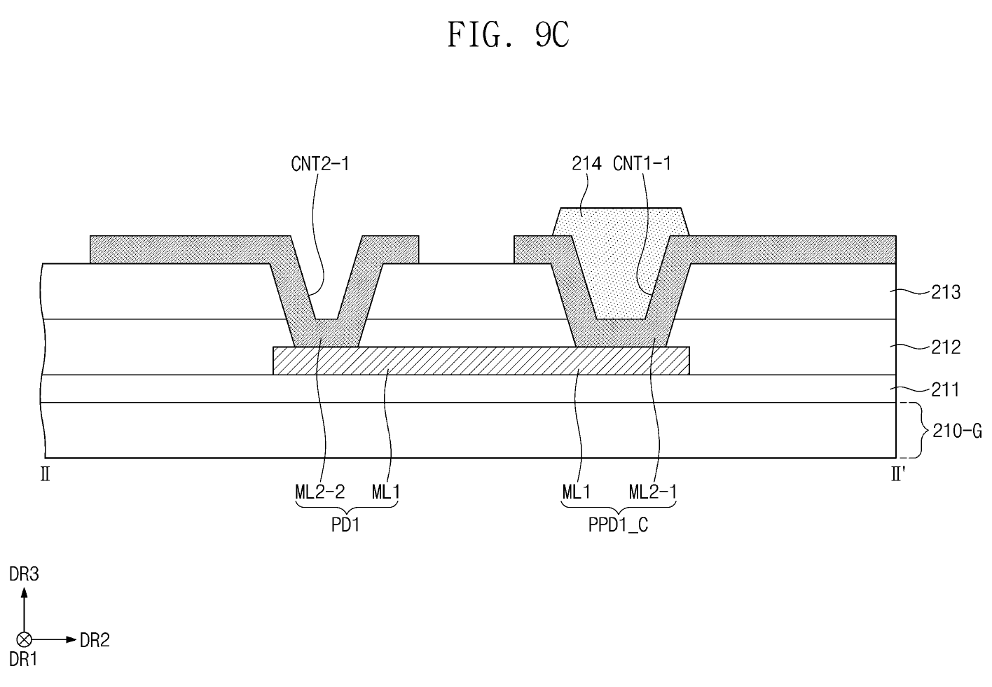

FIG. 8 is a plan view illustrating a preliminary display device 200’ according to an embodiment of the present disclosure. FIG. 9A is a plan view of area AA’ in FIG. 8. FIG. 9B is an enlarged plan view of a portion of a power pad of FIG.

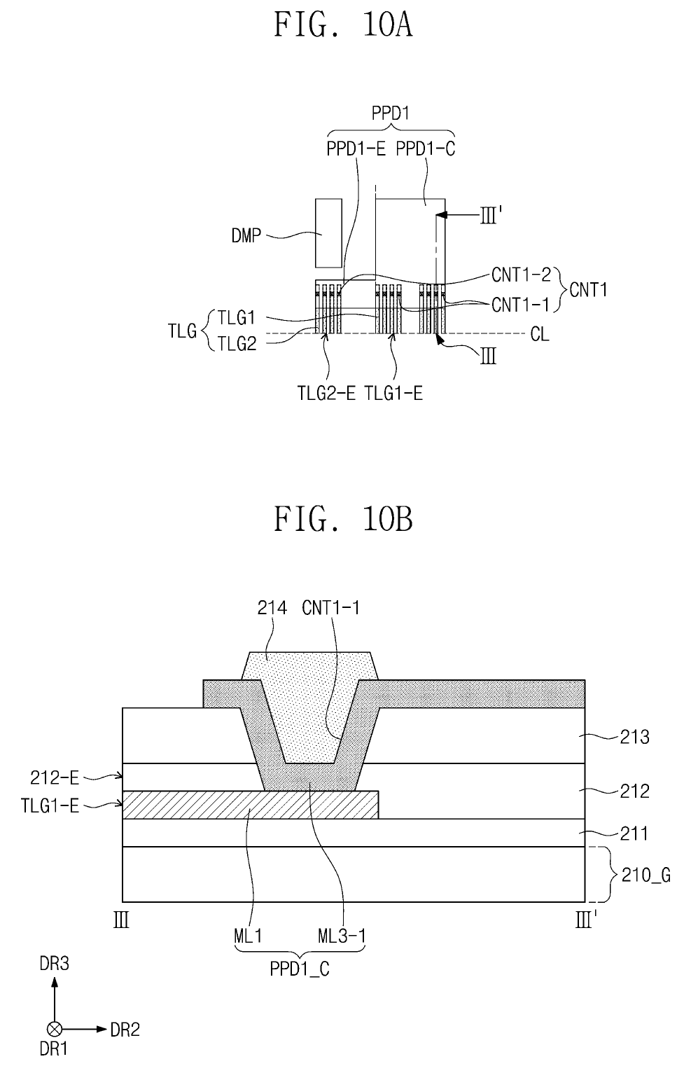

9A. FIG. 9C is a cross-sectional view taken along line II-II’ in FIG. 9B. The preliminary display device 200’ means a display device before reliability of the display panel is completely inspected. FIG. 10A is an enlarged plan view of a portion of the power pad cut by a cutting line CL. FIG. 10B is a cross-sectional view taken along line III-III′ of FIG. 10A.

Hereinafter, any repetitive detailed descriptions of the same or like elements, which are labeled with the or like reference numerals, as those described with reference to FIGS. 5 to 7 will be omitted.

Referring to FIG. 8, an area which does not overlap the encapsulation substrate 210-U and in which the plurality of pads are arranged on the display substrate 210-B may be defined as the pad area PDA. The pad area PDA may be included or defined in the non-display area NAA. An inspection area TA may extend from one end of the pad area PDA in the second direction DR2, and inspection pads electrically connected to the pads in the pad area PDA may be arranged in the inspection area TA. FIG. 8 illustrates an embodiment where a length of the inspection area TA in the first direction DR1 is smaller than a length of the pad area PDA in the first direction DR1, but the present disclosure is not limited thereto. When reliability is completely inspected, the pad area PDA and the inspection area TA may be cut by or along the cutting line CL, and the inspection area TA may be separated from the preliminary display device 200’.

A first inspection pad PPD1_T may be electrically connected to the first power pad PPD1 through an inspection line group TLG (see FIG. 9A) extending in the second direction DR2. A second inspection pad PPD2_T may be electrically connected to the second power pad PPD2 through the inspection line group TLG extending in the second direction DR2.

Referring to FIGS. 9A and 9B, the first power pad PPD1 and a dummy pad DMP may be arranged in the pad area PDA, and the first inspection pad PPD1_T may be disposed in the inspection area TA. A cutting area CLA may be positioned between the pad area PDA and the inspection area TA. The cutting area CLA means an area in which the inspection area TA is separated into the pad area PDA by a separation process which will be described below.

In an embodiment, as shown in FIG. 9B, the first power pad PPD1 includes a connection part PPD1-C and a protrusion part PPD1-E protruding from the connection part PPD1-C in the first direction DR1. The connection part PPD1-C may be a part electrically connected to the flexible circuit board CF (see FIG. 4). The inspection line group TLG may be electrically connected to the first power pad PPD1, and a portion of the inspection line group TLG may be cut and separated from the first power pad PPD1 after the inspection is completed. The inspection line group TLG may include a first inspection line group TLG1 electrically connected to the connection part PPD1-C and a second inspection line group TLG2 electrically connected to the protrusion part PPD1-E. The first inspection line group TLG1 is aligned with the connection part PPD1-C in the second direction DR2 (or overlap the connection part PPD1-C in the third direction DR3), and the second inspection line group TLG2 is aligned with the protrusion part PPD1-E in the second direction DR2 (or overlap the protrusion part PPD1-E in the third direction DR3).

The first power pad PPD1 may be electrically connected to each of the first inspection line group TLG1 and the second inspection line group TLG2 through first contact holes CNT1. The first contact holes CNT1 may include first first contact holes (hereinafter, will be referred to as “(1-1)^{th} contact holes”) CNT1-1 electrically connected to the first inspection line group TLG1 and may include second first contact holes (hereinafter, will be referred to as “(1-2)^{th} contact holes”) CNT1-2 electrically connected to the second inspection line group TLG2. The (1-1)^{th} contact holes CNT1-1 may be located inside the connection part PPD1-C, and the (1-2)^{th} contact holes CNT1-2 may be located inside the protrusion part PPD1-E in a plan view or when viewed in the third direction DR3.

In an embodiment, the first inspection line group TLG1 may include a plurality of first inspection lines. The plurality of first inspection lines may be spaced apart from each other in the first direction DR1. The second inspection line group TLG2 may include a plurality of second inspection lines. The plurality of second inspection lines may be spaced apart from each other in the first direction DR1. The plurality of first inspection lines may be spaced apart from each other in the first direction DR1 to form a slit pattern, and the plurality of second inspection lines may be spaced apart from each other in the first direction DR1 to form a slit pattern. As the first inspection line group TLG1 and the second inspection line group TLG2 may be cut by the cutting line CL which will be described below, portions of the first inspection line group TLG1 and the second inspection line group TLG2 may be exposed to the outside through a cutting surface (or a surface after cut). The first inspection line group TLG1 and the second inspection line group TLG2 may include molybdenum (Mo), which may be corroded when exposed to moisture and oxygen. Even when molybdenum (Mo) is corroded to cause swelling, the first inspection line group TLG1 and the second inspection line group TLG2 may include the spaced inspection lines, and thus the corrosion may be effectively prevented from being spread. As the first inspection line group TLG1 and the second inspection line group TLG2 may include the plurality of spaced inspection lines, expansion of the display panel due to corrosion may be effectively prevented, and structural stability may be improved.

Referring to FIGS. 9A and 9B, the dummy pad DMP may be disposed in the pad area PDA. The dummy pad DMP may be provided as a plurality of dummy pads DMP, and the plurality of dummy pads DMP may include a first dummy pad DMP1, a second dummy pad DMP2, and a third dummy pad DMP3 spaced apart from the first power pad PPD1. However, the number of dummy pads is not limited thereto, and other dummy pads may be additionally included. In an embodiment, as illustrated in FIG. 9B, the dummy pad DMP may be spaced apart from the connection part PPD1-C in the first direction DR1 and may be spaced apart from the protrusion part PPD1-E in the second direction DR2. A length of the dummy pad DMP in the second direction DR2 may be smaller than a length of the connection part PPD1-C in the second direction DR2. As the first power pad PPD1 includes the protrusion part PPD1-E, the length of the dummy pad DMP in the second direction DR2, which is aligned with the protrusion part PPD1-E in the second direction DR2, may be smaller than a length of the first power pad PPD1 in the second direction DR2.

In an embodiment, the first inspection line group TLG1 may include a first first inspection line group (hereinafter, will be referred to as “(1-1)^{th} inspection line group”) and a second first inspection line group (hereinafter, will be referred to as “(1-2)^{th} inspection line group”) spaced apart from the (1-1)^{th} inspection line group in the first direction DR1. Each of the (1-1)^{th} inspection line group and the (1-2)^{th} inspection line group may be electrically connected to the first power pad PPD1 through the (1-1)^{th} contact holes CNT1-1. Some of the (1-1)^{th} contact holes CNT1-1 may be connected to the (1-1)^{th} inspection line group, and the others thereof may be connected to the (1-2)^{th} inspection line group spaced apart in the first direction DR1. The (1-1)^{th} inspection line group and the (1-2)^{th} inspection line group may have a branched form but may receive a same signal from the first power pad PPD1.

In an embodiment, the inspection pads PPD1_T electrically connected to the first power pad PPD1 through the inspection line group TLG may be arranged inside the inspection area TA of the preliminary display device 200’. The inspection pads PPD1_T may include first inspection pads PD1 and PD2 electrically connected to the connection part PPD1-C through the first inspection line group TLG1 and may include a second inspection pad PD3 electrically connected to the protrusion part PPD1-E through the second inspection line group TLG2.

The inspection pads PPD1_T may be electrically connected to the inspection line group TLG through a second contact hole CNT2. Each of the first inspection pads PD1 and PD2 may be electrically connected to the first inspection line group TLG1 through a first second contact hole (hereinafter, will be referred to as “(2-1)^{th} contact hole”) CNT2-1, and the second inspection pad PD3 may be electrically connected to the second inspection line group TLG2 through a second second contact hole (hereinafter, will be referred to as “(2-2)^{th} contact hole”) CNT2-2. The first inspection pads PD1 and PD2 may include the (1-1)^{th} inspection pad PD1 and the (1-2)^{th} inspection pad PD2. The (1-1)^{th} inspection pad PD1 may be electrically connected to the branched (1-1)^{th} inspection line group, and the (1-2)^{th} inspection pad PD2 may be electrically connected to the branched (1-2)^{th} inspection line group.

FIG. 9C illustrates cross sections of the pad area PDA, the cutting area CLA, and the inspection area TA of the preliminary display device 200’ (see FIG. 8). Referring to FIGS. 9A to 9C together, a first insulating layer 211 may be disposed on the base substrate 210-G. A first metal layer ML1 may be disposed on the first insulating layer 211. The first inspection line group TLG1 and the second inspection line group TLG2 may correspond to (or be defined by) the first metal layer ML1. A second insulating layer 212 may be disposed on the first metal layer ML1. The first inspection line group TLG1 and the second inspection line group TLG2 may be arranged between the first insulating layer 211 and the second insulating layer 212. A third insulating layer 213 may be disposed on the second insulating layer 212. Second metal layers ML2-1 and ML2-2 may be arranged on the third insulating layer 213. The second metal layers ML2-1 and ML2-2 may include a first second metal layer (hereinafter, will be referred to as “(2-1)^{th} metal layer”) ML2-1 and a second second metal layer (hereinafter, will be referred to as “(2-2)^{th} metal layer”) ML2-2. The (2-1)^{th} metal layer ML2-1 and the (2-2)^{th} metal layer ML2-2 may be spaced apart from each other in the second direction DR2. Each of the (2-1)^{th} metal layer ML2-1 and the (2-2)^{th} metal layer ML2-2 may be electrically connected to the first metal layer ML1 through a contact hole defined through the second insulating layer 212 and the third insulating layer 213. The connection part PPD1-C of the first power pad PPD1 may correspond to (or be defined by) the (2-1)^{th} metal layer ML2-1, and the (1-1)^{th} inspection pad PD1 may correspond to (or be defined by) the (2-2)^{th} metal layer ML2-2.

In such an embodiment, the (2-1)^{th} metal layer ML2-1 may be electrically connected to the first metal layer ML1 through the (1-1)^{th} contact hole CNT1-1 defined through the second insulating layer 212 and the third insulating layer 213. The (2-2)^{th} metal layer ML2-2 may be electrically connected to the first metal layer ML1 through the (2-1)^{th} contact hole CNT2-1 defined through the second insulating layer 212 and the third insulating layer 213.

In an embodiment, the first metal layer ML1 may include molybdenum (Mo), aluminum (Al), copper (Cu), or the like. Each of the (2-1)^{th} metal layer ML2-1 and the (2-2)^{th} metal layer ML2-2 may have a multi-layer structure. The (2-1)^{th} metal layer ML2-1 and the (2-2)^{th} metal layer ML2-2 may have a three-layer structure stacked in an order of titanium (Ti), aluminum (Al), and titanium (Ti).

A protective layer 214 may cover the (1-1)^{th} contact hole CNT1-1 and may be disposed on the (2-1)^{th} metal layer ML2-1. The protective layer 214 may be formed as a single layer or multiple layers as a film made of an organic material or an inorganic material. The protective layer 214 may be disposed to overlap at least a portion of the (2-1)^{th} metal layer ML2-1 corresponding to an upper conductive layer.

In an embodiment, the (1-1)^{th} inspection pad PD1 may have a same stacked structure as the first power pad PPD1, and the (1-1)^{th} inspection pad PD1 and the (1-2)^{th} inspection pad PD2 may have a same stacked structure as each other. The second inspection pad PD3 may have a same stacked structure as the first power pad PPD1.

Referring back to FIG. 9B, a burnt BT may occur in some of the inspection lines during reliability inspection, which will be described below, and thus some of the inspection lines may be disconnected. For example, the burnt BT may occur in the first inspection line group TLG1 connected to the connection part PPD1-C and may not be electrically connected to the first inspection pads PD1 and PD2. As the burnt BT does not occur in the second inspection line group TLG2 connected to the protrusion part PPD1-E, electric connection between the first power pad PPD1 and the second inspection pad PD3 may be maintained. Even when some of the inspection lines are disconnected during the reliability inspection, the reliability inspection may be performed through the second inspection pad PD3 connected to the protrusion part PPD1-E. Accordingly, the reliability of the inspection of the display panel may be improved, and the reliability of the inspection of the electronic device including the display panel may also be improved.

FIG. 10A illustrates a pad in which lower areas are cut with respect to the cutting line CL illustrated in FIG. 9B. Even when the burnt BT occurs in the portion of the inspection line group TLG, when the reliability inspection is completed, the portion of the inspection line group TLG may be separated from the cutting line CL. The portion of the inspection line group TLG may be removed by the cutting line CL. A cutting surface may be formed in each of the first inspection line group TLG1 and the second inspection line group TLG2 by the cutting line CL. A cutting surface TLG1-E formed along the cutting line CL may be defined in the first inspection line group TLG1, and a cutting surface TLG2-E formed along the cutting line CL may be defined in the second inspection line group TLG2.

Referring to FIG. 10B, a side surface of the display panel may be defined along the cutting line CL. A cutting surface 212-E of the second insulating layer 212 may define the side surface of the display panel. A cutting surface of the first metal layer ML1 may correspond to the cutting surface TLG1-E of the first inspection line group TLG1. The cutting surface 212-E of the second insulating layer 212 may be aligned with the cutting surface TLG1-E of the first inspection line group TLG1 and the cutting surface TLG2-E of the second inspection line group TLG2. That is, the cutting surface 212-E of the second insulating layer 212 may be on a same plane as the cutting surface TLG1-E of the first inspection line group TLG1 and the cutting surface TLG2-E of the second inspection line group TLG2, or the cutting surface 212-E of the second insulating layer 212, the cutting surface TLG1-E of the first inspection line group TLG1 and the cutting surface TLG2-E of the second inspection line group TLG2 may collectively define a same surface.

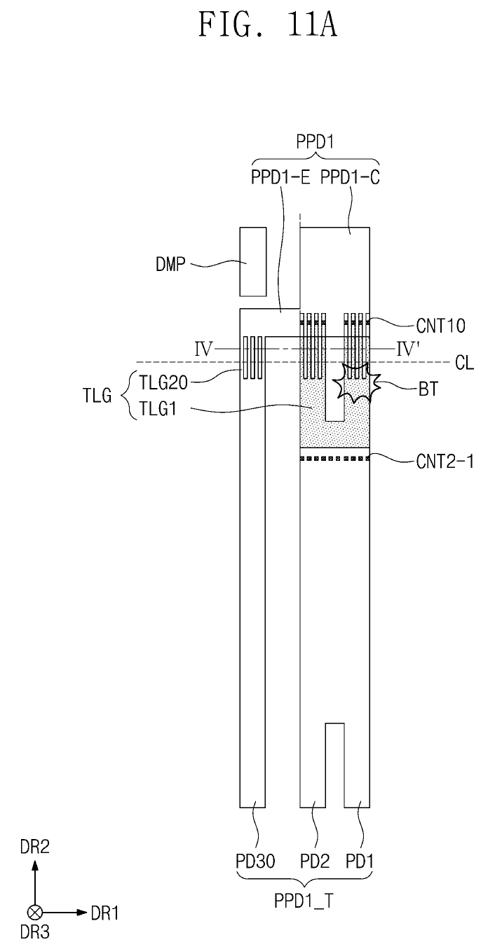

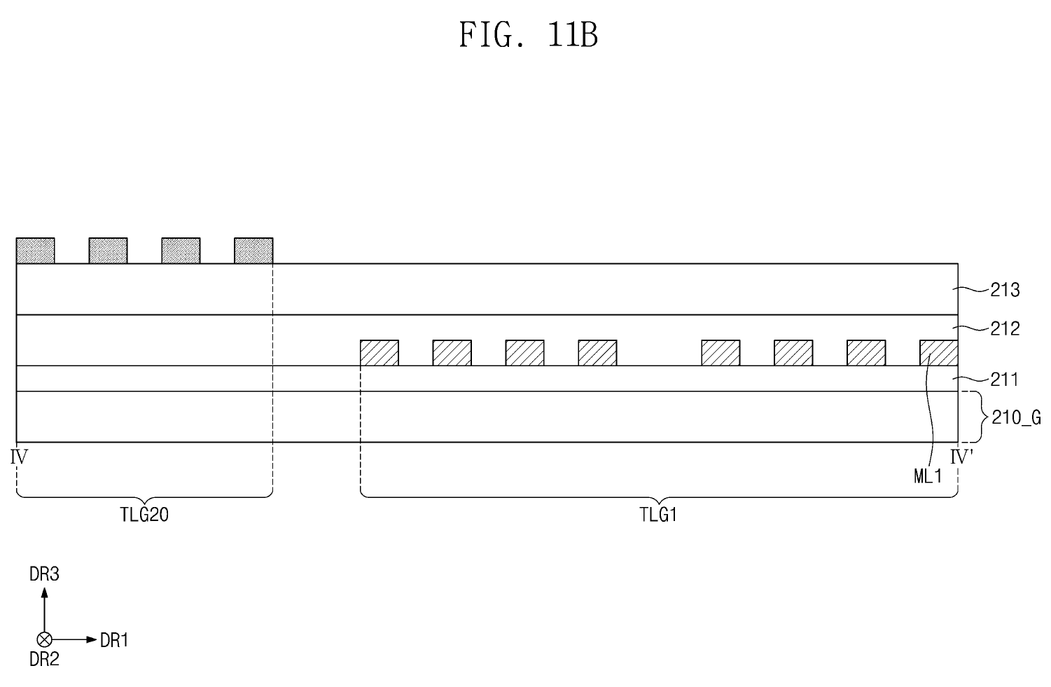

FIG. 11A is an enlarged plan view of a portion of the power pad according to an embodiment of the present disclosure. FIG. 11B is a cross-sectional view taken along line IV-IV′ in FIG. 11A. In description of the embodiment of FIG. 11A, the same or like elements are labeled with the same reference characters as used above to describe the embodiment of FIG. 9B, any repetitive detailed description thereof will hereinafter be omitted, and a difference from the embodiment of FIG. 9B will be mainly described.

Referring to FIG. 11A, in an embodiment, a second inspection line group TLG20 may extend from the protrusion part PPD1-E in the second direction DR2, and the second inspection line group TLG20 may have an integral shape with the protrusion part PPD1-E, that is, the second inspection line group TLG20 and the protrusion part PPD1-E may be integrally formed as a single unitary indivisible part. The second inspection line group TLG20 may be formed in a slit pattern having the same interval as the first inspection line group TLG1.

Referring to FIG. 11B, the first inspection line group TLG1 and the second inspection line group TLG20 may be arranged in (or directly on) different layers, respectively. The first inspection line group TLG1 and the second inspection line group TLG20 may include different materials from each other. Referring to FIG. 9C and 11B together, the first inspection line group TLG1 may be disposed on the first insulating layer 211 and may correspond to the first metal layer ML1. The second inspection line group TLG20 may be disposed on the third insulating layer 213 and may correspond to (or be defined by) the second metal layer ML2. The first inspection line group TLG1 may include a plurality of inspection lines spaced apart from each other in the first direction DR1, and the second inspection line group TLG20 may include a plurality of inspection lines spaced apart from each other in the first direction DR1. An interval between the plurality of first inspection lines and an interval between the plurality of second inspection lines may be the same as each other. A width of each of the plurality of first inspection lines in the first direction DR1 and a width of each of the second inspection lines in the first direction DR1 may be the same as each other.

FIG. 12 is an enlarged plan view of a portion of the power pad according to an embodiment of the present disclosure.

In description of the embodiment of FIG. 12, the same or like elements are labeled with the same reference characters as used above to describe the embodiment of FIG. 9B, any repetitive detailed description thereof will hereinafter be omitted, and a difference from describe the embodiment of FIG. 9B will be mainly described. The first inspection pads PD1 and PD2 and the second inspection pad PD3 may extend in the second direction DR2. A length of the second inspection pad PD3 in the second direction DR2 may be smaller than a length of the first inspection pads PD1 and PD2 in the second direction DR2. Thus, during the reliability inspection which will be described below, contact positions of the first inspection pads PD1 and PD2 and the second inspection pad PD3 in the second direction DR2 may be different from each other.

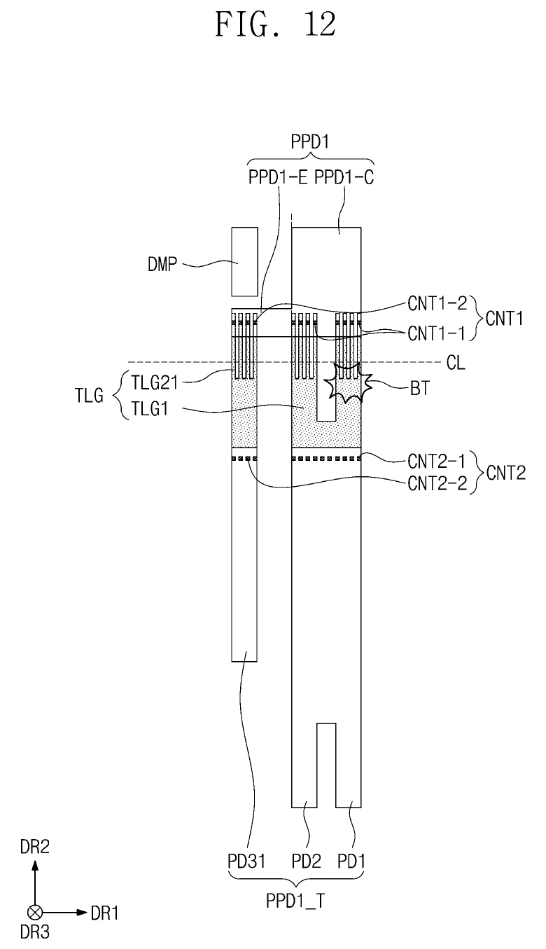

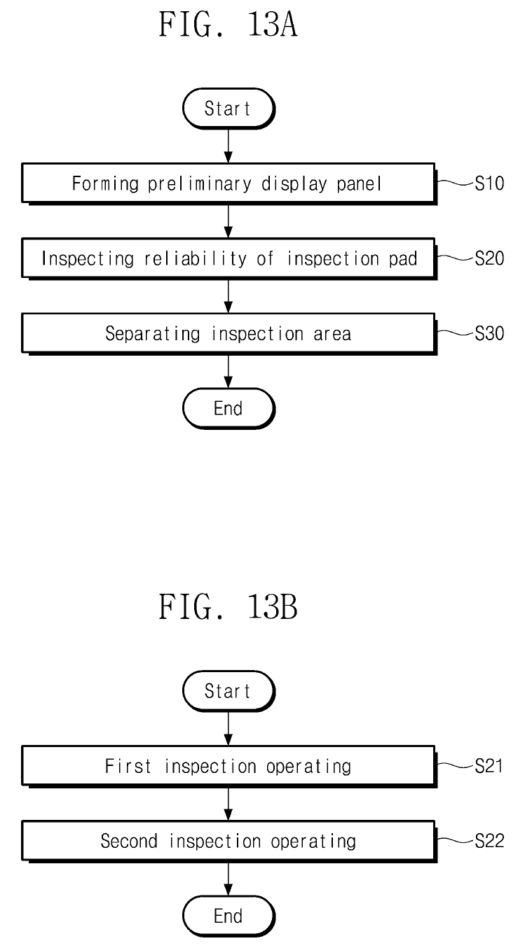

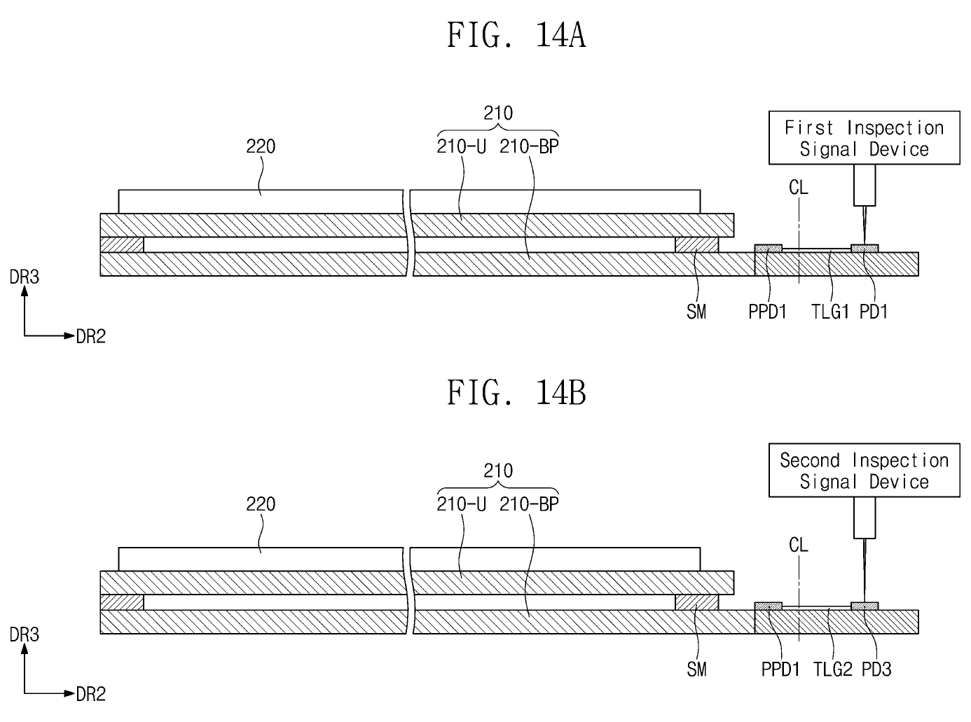

FIG. 13A is a flowchart of a portion of a method of manufacturing a display device according to an embodiment of the present disclosure. FIG. 13B is a flowchart of a method of inspecting reliability of a display device according to an embodiment of the present disclosure. FIG. 14A is a cross-sectional view illustrating a first inspection of the display device according to an embodiment of the present disclosure. FIG. 14B is a cross-sectional view illustrating a second inspection of the display device according to an embodiment of the present disclosure.

Referring to FIGS. 8 and 13A together, an embodiment of a method of manufacturing a display device includes operation S10 of forming a preliminary display panel, operation S20 of performing reliability inspection on the inspection pads PPD1_T and PPD2_T arranged in the inspection area TA, and operation S30 of separating the inspection area TA from the non-display area NAA.

In an embodiment, the inspection area TA may be separated from the pad area PDA. The operation of separating the inspection area TA may be performed by laser trimming. The inspection area TA may be separated based on the cutting line CL.

The operation of separating the inspection area TA may further include an operation of polishing a cutting surface of the non-display area NAA formed by the laser trimming. As the inspection area TA is separated based on the cutting line CL, a portion of the inspection line group TLG (see FIG. 9A) may be cut. Referring to FIGS. 10A and 10B together, a side surface of the cut inspection line group TLG and side surfaces of the insulating layers 211, 212, and 213 may be polished. Accordingly, the cutting surface of the inspection line group TLG and the cutting surfaces of the insulating layers 211, 212, and 213 may be aligned in the second direction DR2.

Referring to FIGS. 13B, 14A, and 14B together, a method of inspecting reliability of a display device may include first inspection operation S21 and second inspection operation S22.

In first inspection operation S21, a first inspection signal may be applied to the first inspection pad PD1 in a way such that a reverse current flows through the light emitting element of the pixel. In second inspection operation S22, a second inspection signal may be applied to the second inspection pad PD3 in a way such that a normal current flows through the light emitting element of the pixel.

Referring to FIGS. 7, 8, and 14A together, the first inspection signal in first inspection operation S21 may be applied through a first inspection signal device. The first inspection signal may be an aging signal, and the first inspection may be an aging inspection.

The first inspection signal may be applied to the cathode of the light emitting element OLED through the second power line PL2. The first inspection signal may be a power voltage having a higher potential than a voltage applied to the anode of the light emitting element OLED. That is, the voltage of the first inspection signal may be a voltage having a higher potential than a signal for normal driving, and accordingly, a high current may flow through the first inspection line group TLG1, and a portion of the first inspection line group TLG1 may be disconnected.

The display device in an unstable state may be initially stabilized through the first inspection. As the high voltage is applied, the high current flows through the light emitting element OLED, high-brightness light emission may be performed, and thus initial brightness may be equalized. The first inspection signal device may be in contact with the first inspection pads PD1 and PD2 through a probe but may not be in contact with the second inspection pad PD3.

Referring to FIGS. 7, 8, and 14B together, the second inspection signal in second inspection operation S22 may be applied through a second inspection signal device. The second inspection signal may be a signal for inspecting image quality, and the second inspection may be an image quality inspection.

The second inspection signal may be applied to the cathode of the light emitting element OLED through the second power line PL2. The second inspection signal may be a power voltage having a lower potential than a voltage applied to the anode of the light emitting element OLED. That is, the voltage of the second inspection signal may be a voltage for normal driving.

As the normal voltage is applied, defective pixels may be detected through the second inspection, and uniformity of brightness of the entire screen may be identified or checked. The second inspection signal device may not be in contact with the first inspection pads PD1 and PD2 to which the high voltage has been applied but may be in contact with the second inspection pad PD3 through the probe. That is, the burnt BT (see FIG. 9B) may occur due to the high voltage, and thus the second inspection may be performed through the second inspection line group TLG2 separated from the first inspection line group TLG1 that may be disconnected, and the reliability may be inspected. Accordingly, accuracy of the reliability inspection of the display device may be improved.

According to an embodiment of the present disclosure, an electronic device includes a display panel, where the display panel includes a power pad including a connection part and a protrusion part, a first inspection line group aligned with the connection part and electrically connected to the connection part, and a second inspection line group aligned with the protrusion part and electrically connected to the protrusion part. Even when the first inspection line group is disconnected during reliability inspection, the reliability inspection may be performed through the second inspection line group, thereby improving inspection reliability.

According to an embodiment of the present disclosure, in a method of manufacturing a display device and a method of inspecting reliability of a display device, the display panel may be included, thereby improving reliability of the reliability inspection.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising:
a display panel;
wherein the display panel includes:
a pixel;
a power voltage line which supplies a voltage to the pixel;
a power pad electrically connected to the power voltage line, wherein the power pad includes a connection part and a protrusion part protruding from the connection part in a first direction;
a first inspection line group electrically connected to the power pad and aligned with the connection part in a second direction intersecting the first direction; and
a second inspection line group electrically connected to the power pad and aligned with the protrusion part in the second direction.

2. The electronic device of claim 1, wherein the first inspection line group includes a plurality of first inspection lines,
wherein the plurality of first inspection lines are spaced apart from each other in the first direction,
wherein the second inspection line group includes a plurality of second inspection lines, and
wherein the plurality of second inspection lines are spaced apart from each other in the first direction.

3. The electronic device of claim 1, wherein the display panel further includes an insulating layer in contact with the first inspection line group and the second inspection line group, and the insulating layer includes a cutting surface defining a side surface of the display panel,
wherein each of the first inspection line group and the second inspection line group includes a cutting surface, and
wherein the cutting surface of the insulating layer is aligned with the cutting surface of each of the first inspection line group and the second inspection line group in a plan view.

4. The electronic device of claim 1, wherein the display panel further includes a dummy pad spaced apart from the connection part in the first direction and spaced apart from the protrusion part in the second direction, and
wherein a length of the dummy pad in the second direction is smaller than a length of the connection part in the second direction.

5. The electronic device of claim 1, wherein the first inspection line group includes a first first inspection line group and a second first inspection line group spaced apart from the first first inspection line group in the first direction.

6. The electronic device of claim 1, wherein the display panel further includes:
a base substrate;
a first insulating layer disposed on the base substrate; and
a second insulating layer disposed on the first insulating layer,
wherein the first inspection line group and the second inspection line group are arranged between the first insulating layer and the second insulating layer, and
wherein the power pad is electrically connected to the first inspection line group and the second inspection line group through a first contact hole defined through the second insulating layer.

7. The electronic device of claim 6, wherein the first contact hole is provided as a plurality of first contact holes, and
wherein, in a plan view, at least one of the plurality of first contact holes is located inside the connection part, and at least another one of the plurality of first contact holes is located inside the protrusion part.

8. The electronic device of claim 1, wherein the second inspection line group extends from the protrusion part in the second direction, and the second inspection line group and the protrusion part are integrally formed as a single unitary indivisible part.

9. The electronic device of claim 8, wherein the first inspection line group and the second inspection line group are disposed in different layers, respectively.

10. The electronic device of claim 1, further comprising:
a power module which supplies power to the display panel;
a processor which controls an operation of the display panel; and
a circuit board connected to the connection part.

11. A method of manufacturing a display device, the method comprising:
forming a preliminary display panel in which a display area, a non-display area disposed around the display area, and an inspection area extending from one end of the non-display area are defined;
performing reliability inspection on inspection pads disposed inside the inspection area; and
separating the inspection area from the non-display area,
wherein the preliminary display panel includes:
a pixel disposed inside the display area;
a power voltage line disposed inside the non-display area, wherein the power voltage line supplies a voltage to the pixel;
a power pad disposed inside the non-display area and electrically connected to the power voltage line, wherein the power pad includes a connection part and a protrusion part protruding from the connection part in a first direction;
a first inspection line group electrically connected to the power pad and aligned with the connection part in the first direction;
a second inspection line group electrically connected to the power pad and aligned with the protrusion part in the first direction;
a first inspection pad disposed inside the inspection area and electrically connected to the connection part through the first inspection line group; and
a second inspection pad electrically connected to the protrusion part through the second inspection line group.

12. The method of claim 11, wherein the separating the inspection area from the non-display area is performed by laser trimming.

13. The method of claim 12, wherein the separating the inspection area from the non-display area further includes:
polishing a cutting surface of the non-display area formed by the laser trimming.

14. The method of claim 11, wherein the first inspection pad and the second inspection pad extend in a second direction intersecting the first direction, and
wherein a length of the second inspection pad in the second direction is smaller than a length of the first inspection pad in the second direction.

15. The method of claim 11, wherein each of the first inspection pad and the second inspection pad has a same stacked structure as the power pad.

16. The method of claim 11, wherein the first inspection pad is electrically connected to the first inspection line group through a first second contact hole, and
wherein the second inspection pad is electrically connected to the second inspection line group through a second second contact hole spaced apart from the first second contact hole in the first direction.

17. A method of inspecting reliability of a display device including a display panel, wherein the display panel includes a pixel, a power voltage line electrically connected to the pixel, a power pad electrically connected to the power voltage line, wherein the power pad includes a connection part and a protrusion part protruding from the connection part in a first direction, a first inspection line group electrically connected to the power pad and aligned with the connection part in a second direction intersecting the first direction, a second inspection line group electrically connected to the power pad and aligned with the protrusion part in the second direction, a first inspection pad electrically connected to the first inspection line group, and a second inspection pad electrically connected to the second inspection line group, the first inspection pad and the second inspection pad being disposed inside an inspection area,
wherein the method of inspecting the reliability of the display device comprises:
performing a first inspection operation by applying a first inspection signal to the first inspection pad in a way that a reverse current flows through a light emitting element of the pixel; and
performing a second inspection operation by applying a second inspection signal to the second inspection pad in a way that a normal current flows through the light emitting element of the pixel.

18. The method of claim 17, wherein, in the performing the first inspection operation, the first inspection signal has a power voltage higher than a voltage applied to an anode of the light emitting element.

19. The method of claim 17, wherein, in the performing the first inspection operation, a portion of the first inspection line group is disconnected.

20. The method of claim 17, wherein, in the performing the second inspection operation, the second inspection signal has a power voltage lower than a voltage applied to an anode of the light emitting element.
